(19) United States
(12) Patent Application Publication
(10) Pub. No.: US 2025/0347756 A1
(43) Pub. Date: Nov. 13, 2025

(54) HIGH-VOLTAGE INTERLOCK CIRCUIT, HIGH-VOLTAGE INTERLOCK DETECTION CIRCUIT, AND HIGH-VOLTAGE DEVICE

(71) Applicant: Robert Bosch GmbH, Stuttgart (DE)

(72) Inventors: Jiayi Xu, Suzhou (CN); Chao Huang, Suzhou (CN); Geralt Yi, Suzhou (CN)

(21) Appl. No.: 19/203,912

(22) Filed: May 9, 2025

(30) Foreign Application Priority Data
May 11, 2024 (CN) 202410585025.6

(51) Int. Cl. G01R 31/67; G01R 31/00

(52) U.S. Cl. CPC G01R 31/67; G01R 31/006

(57) ABSTRACT

Embodiments of the present disclosure relate to a high-voltage interlock circuit, a high-voltage interlock detection circuit, and a high-voltage device. The high-voltage interlock circuit comprises a resistor set, at least one high-voltage interlock connector, and a frequency indication signal generation circuit. The resistor set includes at least one resistor. A single high-voltage interlock connector comprises an interlock detection contact and a power contact. The interlock detection contact is coupled to a respective resistor. In case that a first high-voltage interlock connector is coupled to an external docking connector, the interlock detection contact of the first high-voltage interlock connector is coupled to an interlock detection portion of the docking connector. Equivalent resistance values of the resistor set are determined by coupling states of various interlock detection contacts in the at least one high-voltage interlock connector and the interlock detection portion of the respective docking connector.

### BACKGROUND

Embodiments of the present disclosure relate generally to the technical field of circuits, and specifically relates to a high-voltage interlock circuit, a high-voltage interlock detection circuit, and a high-voltage device.

A high-voltage interlock circuit, which may also be referred to as a high-voltage interlock loop (HVIL), checks the electrical connection integrity of a high-voltage loop in a high-voltage system (e.g., an electric vehicle) by using a low-pressure signal. When the high-voltage loop is disconnected or integrity is compromised, appropriate safety measures need to be activated.

### SUMMARY

Embodiments of the present disclosure provide a high-voltage interlock circuit, a high-voltage interlock detection circuit, and a high-voltage device.

According to a first aspect of the present disclosure, there is provided a high-voltage interlock circuit. The high-voltage interlock circuit comprises: a resistor set comprising at least one resistor; at least one high-voltage interlock connector, wherein a single high-voltage interlock connector comprises an interlock detection contact and a power contact, the interlock detection contact is coupled to a respective resistor in the resistor set, in case that a first high-voltage interlock connector in the at least one high-voltage interlock connector is coupled to an external docking connector, the interlock detection contact of the first high-voltage interlock connector is coupled to an interlock detection portion of the docking connector, and the power contact of the first high-voltage interlock connector is coupled to a power portion of the docking connector, equivalent resistance values of the resistor set are determined by coupling states of various interlock detection contacts in the at least one high-voltage interlock connector and the interlock detection portion of the respective docking connector; and a frequency indication signal generation circuit configured to generate a frequency indication signal according to the equivalent resistance values of the resistor set.

According to a second aspect of the present disclosure, there is provided a high-voltage interlock detection circuit. The high-voltage interlock detection circuit comprises: a high-voltage interlock circuit according to the first aspect of the present disclosure; and a diagnostic circuit configured to detect a frequency of a frequency indication signal and determine coupling states of various interlock detection contacts of the at least one high-voltage interlock connector and the interlock detection portion of a respective docking connector according to the frequency.

According to a third aspect of the present disclosure, there is provided a high-voltage device. The high-voltage device comprises: a high-voltage interlock detection circuit according to the second aspect of the present disclosure.

### BRIEF DESCRIPTION OF THE DRAWINGS

The exemplary embodiments of the present disclosure will be described in further detail in conjunction with accompanying drawings in order to further clarify the above-mentioned and other objectives, features and advantages of the present disclosure, wherein in the exemplary embodiments of the present disclosure, the same reference number typically represents the same parts.

FIG. 1 illustrates a schematic diagram of an exemplary environment in which a high-voltage interlock circuit according to embodiments of the present disclosure may be implemented;

FIG. 2 illustrates a schematic block diagram of a high-voltage interlock circuit according to embodiments of the present disclosure;

FIG. 3 illustrates another schematic block diagram of a high-voltage interlock circuit according to embodiments of the present disclosure;

FIG. 4 illustrates an exemplary circuit diagram of a frequency indication signal generation circuit in the high-voltage interlock circuit of FIG. 2 or FIG. 3;

FIG. 5 illustrates a schematic block diagram of a high-voltage interlock detection circuit according to embodiments of the present disclosure.

In the various accompanying drawings, the same or corresponding numbers represent the same or corresponding portions. It is to be noted that the elements in the figures are schematic and not to scale.

### DETAILED DESCRIPTION

The embodiments of the present disclosure will be described in further detail below with reference to the accompanying drawings. While certain embodiments of the present disclosure are shown in the accompanying drawings, it should be understood that the present disclosure may be implemented in various forms and should not be construed as being limited to the embodiments set forth herein, rather these embodiments are provided for a more thorough and complete understanding of the present disclosure. It should be understood that the accompanying drawings and embodiments of the present disclosure are for exemplary purposes only and are not intended to limit the scope of protection of the present disclosure.

In the description of the embodiments of the present disclosure, the term “comprise” and other similar expressions should be understood as open-ended inclusion, that is, “comprising but not limited to”. The term “based on” should be understood as “at least partially based on”. The term “one embodiment” or “this embodiment” should be understood as “at least one embodiment”. The terms “first”, “second”, etc. may refer to and represent different or the same object. The text below may comprise other specific and implicit meanings.

Unless defined otherwise, all terms used herein (including technical and scientific terms) have the same meaning as commonly understood by those skilled in the art to whom the present subject matter is directed. It will further be understood that terms such as those defined in commonly-used dictionaries should be construed as having meanings consistent with their meaning in the context of the specification and relevant techniques, and will not be construed in an idealized or overly formal form unless otherwise expressly defined herein. As used herein, a representation that two or more portions are “connected” or “coupled” together shall refer to the incorporation of those portions directly together or through at least one intermediate component.

As previously discussed, the electrical connection integrity of one or more high-voltage loops in a high-voltage system (e.g., an electric vehicle) may be checked by a high-voltage interlock circuit. The high-voltage interlock circuit may generally comprise at least one high-voltage interlock connector, each high-voltage interlock connector being useful to inspect a single high-voltage loop. A single high-voltage interlock connector comprises an interlock detection contact and a power contact. In case that the interlock detection contact of the high-voltage interlock connector is well coupled to the interlock detection portion of the external docking connector (the two are interlocked), the high-voltage interlock connector may be considered to be normally connected. In case that the interlock detection contact of the high-voltage interlock connector is not properly coupled to the interlock detection portion of the docking connector (the two are not interlocked), the high-voltage interlock connector may be considered to be not normally connected. In a high-voltage interlock circuit, when either of the high-voltage interlock connectors is not normally connected, the high-voltage interlock circuit forms an open circuit and sends an open circuit indication signal to an external diagnostic circuit. At this point, the external diagnostic circuit can judge that the high-voltage interlock circuit is abnormal, but it is not possible to know which high-voltage interlock connector is not normally connected.

If which high-voltage interlock connector is not normally connected can be accurately judged, it is helpful to rapidly position to the corresponding high-voltage loop to enable safety measures against this high-voltage loop. To this end, the present disclosure proposes a high-voltage interlock circuit that is capable of not only indicating that a high-voltage interlock circuit is abnormal, but also capable of indicating which high-voltage interlock connector is not normally connected in order to improve diagnostic efficiency, thereby helping service personnel to activate safety measures more quickly for failed high-voltage loops.

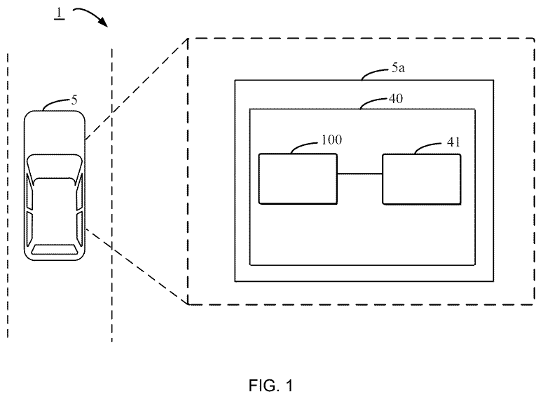

Embodiments of the present disclosure will be described in further detail below in conjunction with the accompanying drawings, wherein FIG. 1 illustrates an exemplary environment in which the high-voltage interlock circuit according to the embodiments of the present disclosure may be implemented.

As shown in FIG. 1, the exemplary environment 1 comprises a vehicle 5. A high-voltage device 5a (e.g., a vehicle air conditioning compressor) may be provided in the vehicle 5. At least one high-voltage loop (not shown) and a high-voltage interlock detection circuit 40 may be provided in the high-voltage device 5a. The high-voltage interlock detection circuit 40 is used for detecting connection states of various high-voltage loops. The high-voltage interlock detection circuit 40 may comprise a high-voltage interlock circuit 100 and a diagnostic circuit 41 according to embodiments of the present disclosure. The high-voltage interlock detection circuit 40 will be described below with reference to FIG. 5. The high-voltage interlock circuit 100 is first described according to embodiments of the present disclosure.

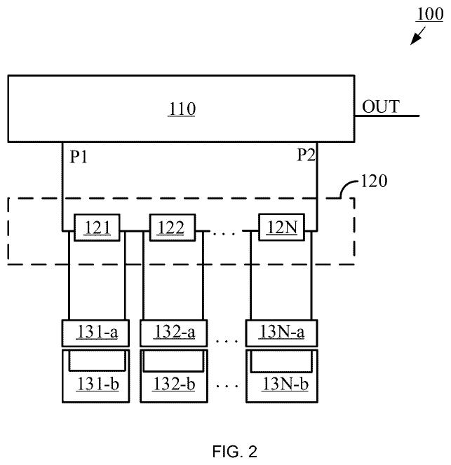

FIG. 2 illustrates a schematic block diagram of a high-voltage interlock circuit 100 according to embodiments of the present disclosure. In the example of FIG. 2, the high-voltage interlock circuit 100 comprises: a resistor set 120, at least one high-voltage interlock connector 131-a, 132-a, . . . , 13N-a, and a frequency indication signal generation circuit 110.

The resistor set 120 comprises at least one resistor 121, 122, . . . , 12N. In some embodiments of the present disclosure, as shown in FIG. 2, the at least one resistor 121, 122, . . . , 12N is connected in series with each other. In an alternative example of FIG. 2, one or more resistors in the resistor set 120 may also be connected in parallel. For example, the resistor 121 may be replaced with two or more resistors in parallel. In other words, there may be some resistors in the resistor set 120 in parallel, and these parallel resistors may be connected in series with other resistors.

N may be an integer greater than or equal to 1 herein. In case that N is equal to 1, the at least one high-voltage interlock connector 131-a, 132-a, . . . , 13N-a may comprise only one high-voltage interlock connector 131-a, and the resistor set 120 may comprise only one resistor 121. In case that N is equal to 2, the at least one high-voltage interlock connector 131-a, 132-a, . . . , 13N-a may comprise only two high-voltage interlock connectors 131-a, 132-a, and the resistor set 120 may comprise only two resistors 121, 122.

A single high-voltage interlock connector in the at least one high-voltage interlock connector 131-a, 132-a, . . . , 13N-a comprises an interlock detection contact and a power contact (not shown). The interlock detection contact is coupled to a respective resistor in the resistor set. In case that the at least one high-voltage interlock connector 131-a, 132-a, . . . , 13N-a is coupled to an external docking connector of the first high-voltage interlock connector, the interlock detection contact of the first high-voltage interlock connector is coupled to an interlock detection portion of the docking connector, and the power contact of the first high-voltage interlock connector is coupled to the power portion of the docking connector. “First high-voltage interlock connector” may refer herein to any high-voltage interlock connector in the at least one high-voltage interlock connector 131-a, 132-a, . . . , 13N-a.

In the example of FIG. 2, the interlock detection contact of the high-voltage interlock connector 131-a comprises two conductive terminals, the interlock detection portion of the docking connector 131-b comprises respective two conductive terminals, and the two conductive terminals are electrically connected to one another (i.e., short-circuited). The two conductive terminals of the interlock detection contact of the high-voltage interlock connector 131-a are coupled to both ends of the resistor 121. Although it is shown in FIG. 2 that two conductive terminals of the interlock detection contact are directly coupled to both ends of the resistor 121, those skilled in the art should appreciate that two conductive terminals of the interlock detection contact may also be coupled to both ends of the resistor 121 via one or more intermediate parts (e.g., resistors or other electrical elements). In case that the high-voltage interlock connector 131-a is coupled to the docking connector 131-b, the interlock detection contact of the high-voltage interlock connector 131-a is coupled to the interlock detection portion of the docking connector 131-b, such that the two conductive terminals of the interlock detection contact are short-circuited, and the power contact (not shown) of the high-voltage interlock connector 131-a is coupled to the power portion (not shown) of the docking connector 131-b. Therefore, the circuit to which the power contact is coupled and the circuit to which the power portion is coupled are included in one loop.

Similarly, the high-voltage interlock connector 132-a may be coupled to the docking connector 132-b. The interlock detection contact of the high-voltage interlock connector 132-a is coupled to the resistor 122. The high-voltage interlock connector 13N-a may be coupled to the docking connector 13N-b in a similar fashion. The interlock detection contact of the high-voltage interlock connector 13N-is coupled to the resistor 12N.

A corresponding relationship of the high-voltage interlock connector to the resistor is preset. The resistors to which various high-voltage interlock connectors correspond are different. Although it is shown in FIG. 2 that the number of resistors is equal to the number of high-voltage interlock connectors, it should be appreciated by those skilled in the art that, in the alternative example of FIG. 2, the number of resistors may be greater than the number of high-voltage interlock connectors. Thus, one or more resistors in the resistor set 120 may not correspond to the high-voltage interlock connectors.

The equivalent resistance values of the resistor set 120 are determined by the coupling states of the various high-voltage interlock connectors and the respective docking connector in the at least one high-voltage interlock connector 131-a, 132-a, . . . , 13N-a. In some embodiments of the present disclosure, in case that the at least one resistor 121, 122, . . . , 12N is connected in series with each other and no high-voltage interlock connector is normally connected, the equivalent resistance values of the resistor set 120 are the sum of the resistance values of the at least one resistor 121, 122, . . . , 12N. In case that the first high-voltage interlock connector in the at least one high-voltage interlock connector 131-a, 132-a, . . . , 13N-a is coupled to the docking connector, the two conductive terminals of the interlock detection contact of the first high-voltage interlock connector are short-circuited, causing the first resistor to be short-circuited, thereby changing the equivalent resistance values of the resistor set 120. In this instance, the equivalent resistance value of the resistor set 120 is equal to the sum of the resistance values of the at least one resistor 121, 122, . . . , 12N minus the resistance value of the first resistor. “First high-voltage interlock connector” may refer herein to any high-voltage interlock connector in the at least one high-voltage interlock connector 131-a, 132-a, . . . , 13N-a. “First resistor” refers to the resistor in the at least one resistor 121, 122, . . . , 12N corresponding to the first high-voltage interlock connector.

The frequency indication signal generation circuit 110 is coupled to the resistor set 120. The frequency indication signal generation circuit 110 is configured to generate a frequency indication signal according to equivalent resistance values of the resistor set 120. In the example of FIG. 2, the frequency indication signal is output from the output terminal OUT of the frequency indication signal generation circuit 110.

In some embodiments of the present disclosure, the first terminal of the resistor set 120 is coupled to the first input terminal P1 of the frequency indication signal generation circuit 110, and the second terminal of the resistor set 120 is coupled to the second input terminal P2 of the frequency indication signal generation circuit 110. The equivalent resistance value of the resistor set 120 is equal to the resistance value between the first terminal of the resistor set 120 and the second terminal of the resistor set 120. The frequency of the frequency indication signal generated by the frequency indication signal generation circuit 110 is associated with an equivalent resistance value of the resistor set 120. In case that a certain or some high-voltage interlock connectors is/are not normally connected, resulting in a change in the equivalent resistance value of the resistor set 120, the frequency of the frequency indication signal changes accordingly, thereby being capable of indicating that the high-voltage interlock connector is not normally connected.

In some embodiments of the present disclosure, in case that the coupling states of various high-voltage interlock connectors in the at least one high-voltage interlock connector 131-a, 132-a, . . . , 13N-a and the respective docking connector are different, the equivalent resistance values of the resistor set 120 are different. In this way, the equivalent resistance values of the resistor set 120 can indicate which high-voltage interlock connector is or is not normally connected, thereby being capable of improving diagnostic efficiency.

With reference to the example of FIG. 2, in case that the number of resistors in the resistor set 120 is equal to the number of high-voltage interlock connectors, the equivalent resistance value of the resistor set 120 is zero if all the high-voltage interlock connectors are normally connected. Assuming that the high-voltage interlock connector 131-a is not coupled to the docking connector 131-b, the resistor 121 is not short-circuited and the equivalent resistance value of the resistor set 120 is r1. r1 represents the resistance value of the resistor 121. Assuming that the high-voltage interlock connector 132-a is not coupled to the docking connector 132-b, the resistor 122 is not short-circuited and the equivalent resistance value of the resistor set 120 is r2. r2 represents the resistance value of the resistor 122. Assuming that the high-voltage interlock connector 13N-a is not coupled to the docking connector 13N-b, the resistor 12N is not short-circuited and the equivalent resistance value of the resistor set 120 is rN. rN represents the resistance value of the resistor 12N. The resistance value of each of the at least one resistor 121, 122, . . . , 12N may be set differently, and the sum of the resistance value of any one or more resistors is also different from the sum of the resistance value of the other one or more resistors. For example, r1+r2 is not equal to rN. r1+rN is not equal to r2. r2+rN is not equal to r1.

In one example, the resistance values of the at least one resistor 121, 122, . . . , 12N may be set into an equal-scale sequence, e.g., 1:2: . . . :2^{(N-1)}.

In some embodiments of the present disclosure, the high-voltage interlock circuit 100 may further comprise a docking connector. That is, the docking connector is a part of the high-voltage interlock circuit 100. Referring to FIG. 2, the high-voltage interlock circuit 100 may comprise one or more of docking connectors 131-b, 132-b, . . . , 13N-b.

In some embodiments of the present disclosure, the power contact of the high-voltage interlock connector is coupled to a high-voltage power supply, and the power portion of the docking connector is coupled to the high-voltage powered device. In this way, the coupling state of the high-voltage interlock connector and the docking connector can reflect whether the corresponding high-voltage power supply normally supplies power externally.

In some other embodiments of the present disclosure, the power contact of the high-voltage interlock connector is coupled to a high-voltage powered device, and a power portion of the docking connector is coupled to a high-voltage power supply. In this way, the coupling state of the high-voltage interlock connector and the docking connector can reflect whether the corresponding high-voltage powered device is normally powered.

One or both of the high-voltage power supply and the high-voltage powered device herein may be a part of an internal high-voltage loop of a high-voltage device using the high-voltage interlock circuit 100 or a part of an external high-voltage loop of the high-voltage device.

In practical applications, the high-voltage interlock circuit 100 is arranged on the high-voltage side (the side using the high-voltage power supply) and the diagnostic circuit 41 is arranged on the low-pressure side (the side using the low-voltage power supply). The inventors of the present disclosure note that, in order to achieve a safe distance between a high voltage and a low voltage, the high-voltage interlock circuit 100 and the diagnostic circuit 41 need to be arranged further, resulting in the overall area they occupy being larger. To this end, the embodiments of the present disclosure propose the arrangement of an isolation circuit between a high voltage side and a low voltage side to reduce the safety distance required between the high voltage and the low voltage, also to make the coupled noise between the high voltage and the low voltage less, and to improve the electro magnetic compatibility (EMC) of the high-voltage interlock circuit. In examples where the high-voltage interlock detection circuit 40 is applied to the high-voltage device 5a, the isolation circuit may be implemented using an existing isolation channel in the high-voltage device 5a, thereby not adding an area of the high-voltage device 5a.

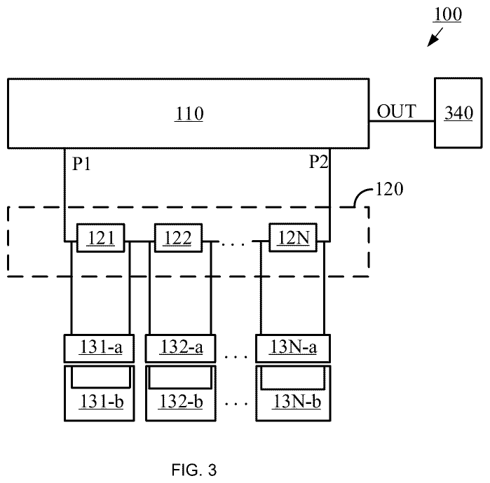

FIG. 3 illustrates a schematic block diagram of a high-voltage interlock circuit 100 in this instance. Based on the high-voltage interlock circuit 100 shown in FIG. 2, the high-voltage interlock circuit 100 in FIG. 3 also comprises an isolation circuit 340. The isolation circuit 340 is coupled to an output terminal OUT of the frequency indication signal generation circuit 110. The isolation circuit 340 is configured to communicate the frequency indication signal to an external diagnostic circuit and electrically isolate a high-voltage circuit to which the at least one high-voltage interlock connector 131-a, 132-a, . . . , 13N-a is coupled from the diagnostic circuit. Here, the high-voltage circuit may refer to a high-voltage circuit outside a high-voltage device using the high-voltage interlock circuit 100, or may be a high-voltage circuit inside the high-voltage device. In one example, the high-voltage circuit may be coupled to a power contact in the high-voltage interlock connector.

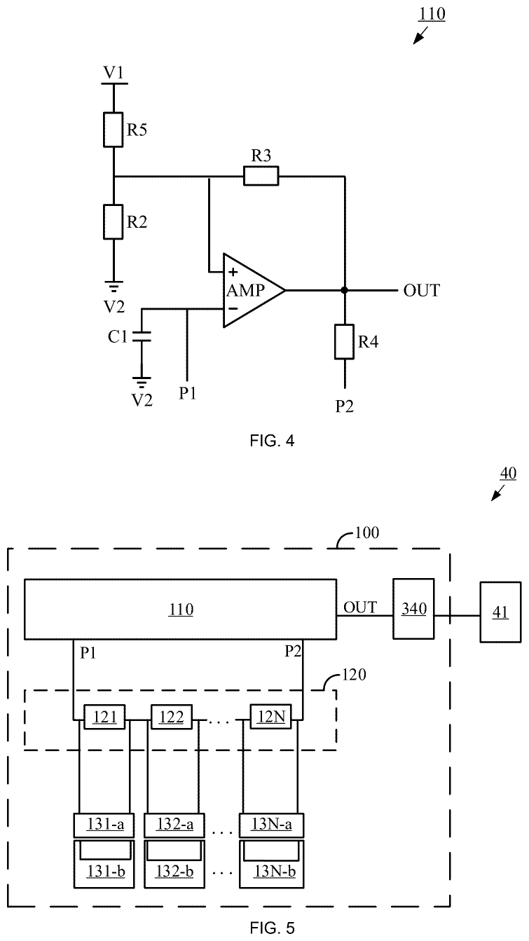

In some embodiments of the present disclosure, the frequency indication signal generation circuit 110 may be an oscillator circuit. FIG. 4 illustrates an exemplary circuit diagram of a frequency indication signal generation circuit 110. In the example of FIG. 4, the frequency indication signal generation circuit 110 may comprise: a second resistor R2, a third resistor R3, a fourth resistor R4, a fifth resistor R5, a capacitor C1, and an operational amplifier AMP.

The first terminal of the fifth resistor R5 is coupled to the first voltage terminal V1. The second terminal of the fifth resistor R5 is coupled to the first terminal of the second resistor R2, the first terminal of the third resistor R3, and the first input terminal of the operational amplifier AMP. The second input terminal of the operational amplifier AMP is coupled to the first terminal of the capacitor C1 and the first input terminal P1 of the frequency indication signal generation circuit 110. The second terminal of the capacitor C1 is coupled to the second voltage terminal V2. A second terminal of the second resistor R2 is coupled to the second voltage terminal V2. The second terminal of the third resistor R3 is coupled to the first terminal of the fourth resistor R4, the output terminal of the operational amplifier AMP, and the output terminal OUT of the frequency indication signal generation circuit 110. The second terminal of the fourth resistor R4 is coupled to the second input terminal P2 of the frequency indication signal generation circuit 110.

In the example of FIG. 4, a high-voltage signal (e.g., 5 V) is input from the first voltage terminal V1, and the second voltage terminal V2 is grounded. The first input terminal of the operational amplifier AMP is an in-phase input terminal. The second input terminal of the operational amplifier AMP is a reverse phase input terminal. It will be understood by those skilled in the art that variations to the circuit shown in FIG. 4 based on the above-described inventive concepts should also fall within the protective scope of the present disclosure. In this variant, the voltage terminals described above may also have different settings than the example shown in FIG. 4. The internal structure of the frequency indication signal generation circuit 110 in FIG. 4 is exemplary and the frequency indication signal generation circuit 110 may also be achieved by other circuits other than the oscillator circuit. Embodiments of the present disclosure do not limit the specific implementation of the frequency indication signal generation circuit 110.

In combination with FIG. 3 and FIG. 4, in case that all high-voltage interlock connectors are normally connected, the equivalent resistance value of the resistor set 120 is zero, and the frequency of the frequency indication signal generation circuit 110 depends on a product of the resistance value of the fourth resistor R4 and the capacitance value of the capacitor C1 (R4×C1). R4 represents the resistance value of the fourth resistor R4, and C1 represents the capacitance value of the capacitor C1.

If the high-voltage interlock connector 131 is not normally connected, the equivalent resistance value of the resistor set 120 is r1 (i.e., the equivalent resistance value between P1 and P2 is r1), and the frequency of the frequency indication signal generation circuit 110 depends on (R4+r1)×C1. If the high-voltage interlock connector 132 is not normally connected, the equivalent resistance value of the resistor set 120 is r2, and the frequency of the frequency indication signal generation circuit 110 depends on (R4+r2)×C1. If the high-voltage interlock connector 131 is not normally connected and the high-voltage interlock connector 132 is not normally connected, the equivalent resistance value of the resistor set 120 is r1+r2, and the frequency of the frequency indication signal generation circuit 110 depends on (R4+r1+r2)×C1. In this way, the frequency of the frequency indication signal generation circuit 110 is capable of reflecting the equivalent resistance value of the resistor set 120, thereby determining which one (or more) resistor in the resistor set 120 is not short-circuited to determine that one (or more) high-voltage interlock connector is not normally connected.

FIG. 5 illustrates a schematic block diagram of a high-voltage interlock detection circuit 40 according to embodiments of the present disclosure. In the example of FIG. 5, the high-voltage interlock detection circuit 40 comprises: a high-voltage interlock circuit 100 and a diagnostic circuit 41. The diagnostic circuit 41 is coupled to the isolation circuit 340 in the high-voltage interlock circuit 100 to receive a frequency indication signal from the frequency indication signal generation circuit 110. The diagnostic circuit 41 is configured to detect a frequency of the frequency indication signal and determine coupling states of various high-voltage interlock connectors in the at least one high-voltage interlock connector 131-a, 132-a, . . . , 13N-a and the respective docking connector based on the detected frequency.

In some embodiments of the present disclosure, the diagnostic circuit 41 may be implemented by a microcontroller unit (MCU). The diagnostic circuit 41 may pre-store a corresponding relationship between the frequency of the frequency indication signal and the connection state of the high-voltage interlock connector, thereby being capable of rapidly determining which one (or more) high-voltage interlock connector is not normally connected based on the detected frequency.

In summary, the high-voltage interlock circuit according to the present disclosure is capable of not only indicating that a high-voltage interlock circuit is abnormal, but also capable of indicating which high-voltage interlock connector is not normally connected in order to improve diagnostic efficiency, thereby helping service personnel to activate safety measures more quickly for failed branch circuits. Further, by arranging an isolation circuit between the high voltage side and the low voltage side, the high-voltage interlock circuit according to embodiments of the present disclosure reduce the security distance required between the high voltage and the low voltage, such that coupled noise between the high voltage and the low voltage is less, and EMC of the high-voltage interlock circuit is increased. Similarly, the high-voltage interlock detection circuit and the high-voltage device according to embodiments of the present disclosure have the same beneficial effect as described above.

The singular forms of the terms used herein and in the appended claims include the plural, and vice versa, unless the context clearly dictates otherwise. As such, when referring to the singular, it is common to include the plural of the respective terms. Where the term “example” is used herein, particularly when it follows a set of terms, the “example” is merely exemplary and illustrative and should not be considered exclusive or broad.

Further aspects and ranges of adaptation become apparent from the description provided herein. It will be understood that various aspects of the present application may be implemented alone or in combination with at least one other aspect. It will also be understood that the description and specific embodiments herein are intended to be illustrative only and are not intended to limit the scope of the present application.

The various embodiments of the present disclosure have been described above. The descriptions provided are exemplary and not exhaustive, and they are also not limited to the disclosed embodiments. M any modifications and variations will be apparent to those skilled in the art without departing from the scope and spirit of the described embodiments. The selection of terms used in this text aims to best explain the principles and actual application of the various embodiments, the technological improvements in the technology in the market, or allow others of ordinary skill in the art to understand the various embodiments disclosed in this text.

What is claimed is:

1. A high-voltage interlock circuit (100), comprising:
a resistor set (120) comprising at least one resistor (121, 122, . . . , 12N);
at least one high-voltage interlock connector (131-a, 132-a, . . . , 13N-a), wherein a single high-voltage interlock connector comprises an interlock detection contact and a power contact, the interlock detection contact is coupled to a respective resistor in the resistor set (120), in case that a first high-voltage interlock connector among the at least one high-voltage interlock connector (131-a, 132-a, . . . , 13N-a) is coupled to an external docking connector, the interlock detection contact of the first high-voltage interlock connector is coupled to an interlock detection portion of the docking connector, and the power contact of the first high-voltage interlock connector is coupled to a power portion of the docking connector, equivalent resistance values of the resistor set (120) are determined by coupling states between various interlock detection contacts in the at least one high-voltage interlock connector and the interlock detection portion of the respective docking connector; and
a frequency indication signal generation circuit (110) configured to generate a frequency indication signal according to the equivalent resistance values of the resistor set (120).

2. The high-voltage interlock circuit (100) according to claim 1, further comprising:
an isolation circuit (340) configured to communicate the frequency indication signal to an external diagnostic circuit (41) and to electrically isolate a high-voltage circuit to which the at least one high-voltage interlock connector (131-a, 132-a, . . . , 13N-a) is coupled from the diagnostic circuit (41).

3. The high-voltage interlock circuit (100) according to claim 1, wherein two conductive terminals of the interlock detection contact are respectively coupled to both ends of a corresponding resistor, and in case that the interlock detection contact of the first high-voltage interlock connector is coupled to the interlock detection portion of the docking connector, the two conductive terminals of the interlock detection contact are short-circuited.

4. The high-voltage interlock circuit (100) according to claim 3, wherein the at least one resistor (121, 122, . . . , 12N) is connected in series with each other.

5. The high-voltage interlock circuit (100) according to claim 4, wherein resistance values of the at least one resistor (121, 122, . . . , 12N) are set into an equal-scale sequence.

6. The high-voltage interlock circuit (100) according to claim 1, wherein a first terminal of the resistor set (120) is coupled to a first input terminal (P1) of the frequency indication signal generation circuit (110), a second terminal of the resistor set (120) is coupled to a second input terminal (P2) of the frequency indication signal generation circuit (110), in case that coupling states between various interlock detection contacts in the at least one high-voltage interlock connector and the interlock detection portion of the respective docking connector are different, equivalent resistance values of the resistor set (120) are different.

7. The high-voltage interlock circuit (100) according to claim 6, the frequency indication signal generation circuit (110) comprising: a second resistor (R2), a third resistor (R3), a fourth resistor (R4), a fifth resistor (R5), a capacitor (C1), an operational amplifier (AMP),
wherein a first terminal of the fifth resistor (R5) is coupled to a first voltage terminal (V1), a second terminal of the fifth resistor (R5) is coupled to a first terminal of the second resistor (R2), a first terminal of the third resistor (R3), and a first input terminal of the operational amplifier (AMP);
a second input terminal of the operational amplifier (AMP) is coupled to a first terminal of the capacitor (C1) and a first input terminal (P1) of the frequency indication signal generation circuit (110);
a second terminal of the capacitor (C1) coupled to a second voltage terminal (V2);
a second terminal of the second resistor (R2) is coupled to the second voltage terminal (V2);
a second terminal of the third resistor (R3) is coupled to a first terminal of the fourth resistor (R4), an output terminal of the operational amplifier (AMP), and an output terminal (OUT) of the frequency indication signal generation circuit (110);
a second terminal of the fourth resistor (R4) is coupled to a second input terminal (P2) of the frequency indication signal generation circuit (110).

8. The high-voltage interlock circuit (100) according to claim 1, further comprising the docking connector,
wherein the power contact of the high-voltage interlock connector is coupled to a high-voltage power supply, the power portion of the docking connector is coupled to a high-voltage powered device; or
the power contact of the high-voltage interlock connector is coupled to the high-voltage powered device, and the power portion of the docking connector is coupled to the high-voltage power supply.

9. A high-voltage interlock detection circuit (40), comprising:
the high-voltage interlock circuit (100) according to claim 1; and
a diagnostic circuit (41) configured to detect the frequency of the frequency indication signal and determine coupling states between various interlock detection contacts in the at least one high-voltage interlock connector (131-a, 132-a, . . . , 13N-a) and the corresponding interlock detection portion of a respective docking connector according to the frequency.

10. A high-voltage device (5a), comprising: the high-voltage interlock detection circuit (40) according to claim 9.
